(19) United States
(12) Patent Application Publication
(10) Pub. No.: US 2021/0018660 A1
(43) Pub. Date: Jan. 21, 2021

(54) POLYMERIC COMPOSITE COMPRISING PARTICLES HAVING A VARYING REFRACTIVE INDEX

(71) Applicant: 3M INNOVATIVE PROPERTIES COMPANY, St. Paul, MN (US)

(72) Inventors: Paul B. Armstrong, St. Paul, MN (US); Bing Hao, Woodbury, MN (US)

(21) Appl. No.: 16/955,376

(22) PCT Filed: Dec. 13, 2018
(86) PCT No.: PCT/IB2018/060044

§ 371 Date: Jun. 18, 2020

Related U.S. Application Data
(60) Provisional application No. 62/608,173, filed on Dec. 20, 2017.

(51) Int. Cl. G02B 5/02; H01L 51/52; C09D 133/08

(52) U.S. Cl. CPC G02B 5/0278; G02B 5/0242; C08K 2003/2296; C09D 133/08; H01L 51/5268

(57) ABSTRACT

Described herein is a composition including a polymeric matrix having a first refractive index, and a plurality of particles dispersed therein, wherein each particle within the plurality of particles comprises an inorganic core and polymer chains grafted thereon, wherein the particle has a second refractive index that is different from the first refractive index.

### TECHNICAL FIELD

A composite material comprising particles having a varying refractive index are discussed. Such composite materials can be used to alter the optical properties of a substrate, such as scatter.

### SUMMARY

There is a need for light diffusers in a variety of optical applications. These diffusers should scatter light at controlled angles. Thus, there is a desire to produce composite compositions that impact optical properties, such as increase the scattering angle of light, while minimally impacting the light's transmittance and/or haze.

In one aspect, a composition is provided, the composition comprising a polymeric matrix having a first refractive index, and a plurality of particles dispersed therein, wherein each particle within the plurality of particles comprises an inorganic core having polymer chains grafted thereon, wherein the particle has a second refractive index that is different from the first refractive index.

In another aspect, a coated article is provided, the coated article comprising a substrate with a composition thereon, wherein the composition comprises a polymeric matrix having a first refractive index, and a plurality of particles dispersed therein, wherein each particle within the plurality of particles comprises an inorganic core having polymer chains grafted thereon, wherein the particle has a second refractive index that is different from the first refractive index.

In yet another aspect, a light diffusing layer is provided, the light diffusing layer comprising a polymeric matrix having a first refractive index, and a plurality of particles dispersed therein, wherein each particle within the plurality of particles comprises an inorganic core having polymer chains grafted thereon, wherein the particle has a second refractive index that is different from the first refractive index.

The above summary is not intended to describe each embodiment. The details of one or more embodiments of the invention are also set forth in the description below. Other features, objects, and advantages will be apparent from the description and from the claims.

### BRIEF DESCRIPTION OF DRAWINGS

FIG. 1 is a schematic of a cross-sectional view of a particle of the present disclosure;

FIG. 2 is a cross-sectional view of a layer including a plurality of particles;

FIG. 3 is a cross-sectional view of a multilayer film having a layer including a plurality of particles; and

FIG. 4 is a schematic cross-sectional view of a film or layer disposed on a display.

### DETAILED DESCRIPTION

In the following description, reference is made to the accompanying drawings that forms a part hereof and in which are shown by way of illustration. The drawings are not necessarily to scale. It is to be understood that other embodiments are contemplated and may be made without departing from the scope or spirit of the present disclosure. The following detailed description, therefore, is not to be taken in a limiting sense.

As used herein, the term

“a”, “an”, and “the” are used interchangeably and mean one or more; and

“and/or” is used to indicate one or both stated cases may occur, for example A and/or B includes, (A and B) and (A or B);

“crosslinking” refers to connecting two pre-formed polymer chains using chemical bonds or chemical groups; and

“monomer” is a molecule which can undergo polymerization which then form part of the essential structure of a polymer.

Also herein, recitation of ranges by endpoints includes all numbers subsumed within that range (e.g., 1 to 10 includes 1.4, 1.9, 2.33, 5.75, 9.98, etc.).

Also herein, recitation of “at least one” includes all numbers of one and greater (e.g., at least 2, at least 4, at least 6, at least 8, at least 10, at least 25, at least 50, at least 100, etc.).

As used herein, the phrase “comprising at least one of” followed by a list refers to comprising any one of the items in the list and any combination of two or more items in the list. The phrase “at least one of” followed by a list refers to any one of the items in the list or any combination of two or more items in the list.

Organic light emitting diode (OLED) displays often produce a light output having a color that varies with view direction. This effect is particularly objectionable in strong cavity OLEDs where a cavity between the cathode and anode of the emissive stack of the OLED has an output that depends on wavelength and view angle. Thus, in one embodiment, it would be desirable to identify compositions which increase scatter and thus, possibly reduce color variation with view angle.

In the present application, it has been discovered that a composite comprising particles having a gradient refractive index, can increase the scattering angle of light, while not substantially impacting its transmittance and/or haze.

The composition of the present disclosure is a composite comprising particles dispersed within a polymeric matrix.

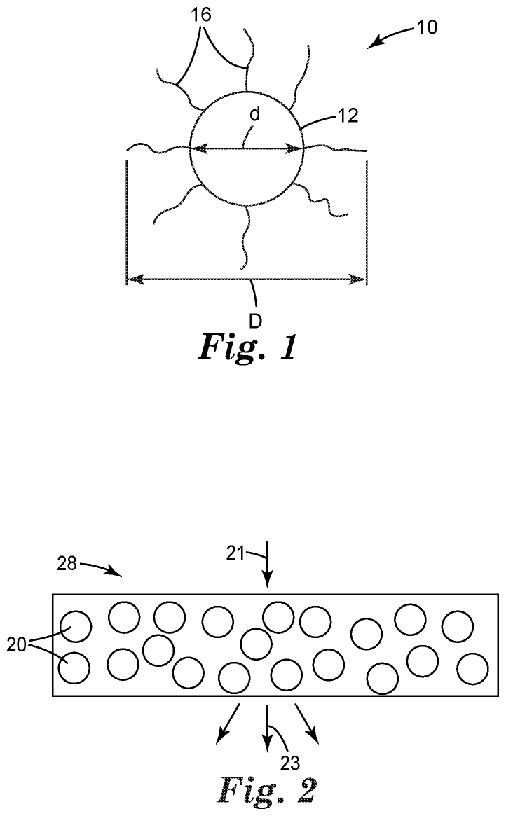

The particles of the present disclosure comprise an inorganic core with polymer chains grafted onto the inorganic core. FIG. 1 is a schematic cross-sectional view of a particle according to the present disclosure. Particle 10 comprises inorganic core 12, having average diameter d. Polymer chains 16 extend from inorganic core 12, giving particle 10 an average diameter D.

The particle cores of the present disclosure are inorganic (i.e., do not comprise any carbon-hydrogen bonds).

In one embodiment, the inorganic core comprises a ceramic, wherein the ceramic may be amorphous, glass, crystalline ceramic, glass-ceramic, substantially glassy, or combinations thereof. Substantially glassy refers to ceramic particles that are amorphous in nature, but may still retain some crystalline character, in other words, it is not fully amorphous. For example, if a crystalline ceramic particle is treated with the process as disclosed in U.S. Pat. No. 5,559,170 (Castle), the crystalline nature of the particle may be reduced, where the surface portions of the particle becomes amorphous in nature, however, the particle may still contain some of its original crystallinity and thus is referred to as substantially glassy. In one embodiment, the inorganic core comprises silica, alumina, and combinations thereof. In one embodiment, the inorganic core comprises a silicate-containing material selected from lithium silicates, alkaline earth aluminosilicates, soda lime silicates, borosilicates, silicon oxide, magnesium alminosilicate, hydrated aluminum silicate, and combinations thereof.

The inorganic cores used in the present disclosure are preferably substantially spherical. The degree of sphericity of a particle is the ratio of the surface area of a sphere of set volume to the surface area of that particle with the same volume. Substantially spherical means that the average degree of spherecity is at least 0.75, 0.8, 0.85, 0.9, 0.95, or even 0.99, with the theroretical sphericity of 1.0 for a perfect sphere.

The inorganic cores are solid, meaning they do not comprise a hollow center (such as particles known as glass bubbles). However, the inorganic cores may contain imperfections, such as low amounts (e.g., less than 20, 10, or even 5%) of undesired bubbles, but imperfections are not preferable.

Typically, the diameter of the inorganic core is sufficiently small to not be visible to the unaided human eye. In one embodiment, the inorganic core has an average diameter, d, of at least 50, 60, 70, or even 80 nm (nanometers); and at most 100, 200, 300, or even 500 nm.

In one embodiment, the inorganic cores have a narrow polydispersity index, for example, less than 2, or even 1.5 when measured using standard particle size measurement techniques such as microscopy or light scattering.

Polymer chains are grafted (i.e., covalently bound) to the inorganic core. The polymer chains extend from the core creating a shell.

The polymer chains are selected to substantially match the refractive index of the inorganic core. In one embodiment, the absolute difference between the refractive index of the polymer used in the grafted polymer chain and the refractive index of the inorganic core is less than 0.05, 0.04, 0.03, 0.02, or even 0.01.

Living polymerization can be used to grow polymer chains from initiators bound to an inorganic particle surface, resulting in an inorganic core grafted with polymer chains extending therefrom. Living polymerizations are techniques used to obtain a narrow polydispersity of resulting particles. Living polymerization techniques are used to minimize disadvantageous side reactions such as chain transfer and chain termination. The absence of the disadvantageous side reactions can result in polymer chains having a more uniform chain length. In one embodiment, the inorganic core is reacted with a functionalized silane to form initiation sites on the inorganic core. The number of initiating sites can vary from an average of one up to 2,000,000 or more depending on particle size and initiation site density. Preferably, the number of functional groups on each inorganic core would be in the range of 10,000 to 2,000,000, and more preferably in the range of 50,000 to 500,000, The number of initiating sites on the inorganic core can be varied by varying the ratio of the moles of surface treating agents relative to the surface area of the core. In one embodiment, the inorganic core comprises at least 0.1, 0.2, 0.5, or even 1.0 initiating sites per mm² (nanometer²) surface area and at most 2.0, 3.0, 4.0, 5.0, or even 10.0 initiating sites per nm² surface area. Control over the number of initiating sites on the inorganic core allows for control of the graft density of the attached polymer chains and thereby the packing density of the polymer chains. A high density of initiating sites provides for maximum incorporation of grafted polymer chains and a high grail density, which provides tethered chains that are in an extended, brush-like state, whereas a loose packing density provides tethered chains that may assume a coiled conformation at higher molar mass.

Both free-radical polymerization and non-free radical polymerization techniques may be used for living polymerization. In non-free radical polymerization, polymerizations as known in the art, including cationic ring opening polymerization, anionic polymerization, and group transfer polymerization, may be used.

More preferably, polymerization is by a free-radical living polymerization. In one embodiment, the inorganic core is functionalized with initiators, which will radically transfer an atom or group. Upon initiation, monomers will polymerize onto the surface of the inorganic core in a controlled fashion, forming polymer chains. The length of the polymer chain can be controlled by the termination of the polymerization process.

Exemplary free radical polymerization processes include nitroxide mediated polymerization, atom transfer radical polymerization, iniferter polymerization, or reversible addition-fragmentation chain transfer polymerization. In one embodiment, the polymerization process is catalyzed by a metal catalyst, such a copper. Such grafting techniques are known in the art, for example U.S. Pat. No. 6,627,314 (Matyjaszewski et al.), herein incorporated by reference. In another embodiment, the initiating sites on the inorganic core are photoiniferters, and the polymerization is initiated by ultraviolet (UV) light. The term photoiniferter refers to a chemical group that has the combined functions of being a photo-initiator for free radical polymerization, a chain transfer agent, and a terminating agent. The use of photoiniferters for producing polymers with controlled architectures is known in the art. Exemplary photoiniferters include xanthates, dithiocarbamates, and trithiocarbonates.

Exemplary polymer chains, which can be grafted onto the inorganic cores include acrylates, methacrylates, acrylamides, methacrylamides, polyamides, polyesters, olefins, styrenes, ring opening polymers, polyesters, and combinations thereof.

Typically, the polymer chains are homopolymers, comprising the same repeat monomeric unit. However, in one embodiment, random copolymers, comprising more than one different monomeric repeat unit in each polymer chain may be used.

In one embodiment, each polymer chain, comprises on average at least 500, 750, 1000 or even 2000 repeat monomeric units.

In one embodiment, the polymer chains have a number average molecular weight of at least 25,000 or even 50,000 g/mol; and at most 100,000, 250,000, 500,000, or even 1 million g/mol.

The polymer chains may be linear or branched depending on the monomers used.

In one embodiment, the polymer chains are not crosslinked, meaning that the polymer chains extend from the inorganic core and may interact with adjacent polymer chains, but are not covalently bound to them.

As will be further discuss herein, the refractive index of the particles is different than that of the polymeric matrix. Thus, in one embodiment, the refractive index of the particle is less than 1.8, 1.7, 1.6, 1.55, or even 1.5, and typically at least 1.3, or even 1.4. The refractive index can be determined by using techniques known in the art. For example, the Becke Line Method wherein certified refractive test liquids are used along with a microscope to determine the refractive index of a material or the refractive index may be determined by using a refractometer and measuring the bend of a wavelength of 589 nm (sodium D line) at 25° C. in air.

The grafted particles are generally spherical in shape.

The resulting diameter of the grafted particle can vary depending on the diameter of the core. Typically, the diameter of the shell is grown to at least 1 time, 2 times, 5 times, or even 10 times the diameter of the core. In one embodiment, the particles having an average diameter (D) of at least 100, 200, 500, or even 750 nm. In one embodiment, the particles having an average diameter (D) of at most 1, 2, 3, 4, or even 5 microns.

The particles of the present disclosure are incorporated into a polymer matrix, typically at an amount of at least 2.0, 3.0, 4.0, or even 5.0 wt %; and at most 8.0, 10, 20, 25, 30, 35, or even 40 wt % based on the weight of the polymeric matrix.

The polymeric matrix of the present disclosure can be for example, a resin or an adhesive.

Suitable polymers or copolymers include polyacrylates, polymethacrylates, polyolefins, polyepoxides, polyethers, and copolymers thereof. Suitable adhesives which may be used as the matrix include pressure sensitive adhesives (PSAs) and hot-melt adhesives. The matrix material may be a curable liquid, such as a UV curable acrylate.

The polymeric matrix comprises at least a polymeric material or a polymerizable material. Such polymeric materials include polyacrylates, polymethacrylates, polyolefins, polyepoxides, poly ethers, polyimides, polyamides, thiol-ene polymers, and conjugated aromatic polymers. Such polymerizable materials include epoxide monomers, (meth)acrylate monomers, thiol-ene monomers, and combinations thereof. If the polymeric matrix comprises polymerizable materials, it may further comprise additional components to create a polymerized matrix as known in the art, such as a crosslinking agent, initiating agent, etc.

The polymer matrix is selected to have a refractive index different from the refractive index of the particles. In one embodiment, the refractive index of the polymer matrix is greater than the refractive index of the particles. In another embodiment, the refractive index of the polymer matrix is lower than the refractive index of the particles. In one embodiment, the absolute difference between the refractive index of the polymer matrix and the refractive index of the particles is greater than 0.10, or even 0.20, and less than 0.50, 0.70, or even 1.0.

In one embodiment, in addition to the polymeric matrix and the particles, the composition may further comprise a second plurality of particles. Such second particles may be used to increase the effective refractive index of the polymeric matrix and/or to increase the durability of the composition. In one embodiment, the second plurality of particles have a diameter less than 20, 10, or even 2 nm; and greater than 0.5 nm. In one embodiment, the second plurality of particles are inorganic particles comprising at least one of zirconia, titania, zinc oxide, and combinations thereof. In one embodiment, the second plurality of particles are not grafted. In one embodiment, this second plurality of particle is present at at least 10, 20, 40, or even 50%; and at most 60 or even 75% versus the weight of the polymeric matrix.

In one embodiment, the compositions of the present disclosure are translucent or transparent. The composition may be substantially transparent (e.g., a layer of the matrix or a layer of the composition may transmit at least 80 percent, or at least 90 percent of light in the wavelength range of 400 to 700 nm).

Although not wanting to be limited by theory, it is believed that the polymers of the polymeric matrix at least partially penetrate the tethered polymer chains of the particles causing the refractive index to change from the outer perimeter of the particles to the inorganic core. If the refractive index of the polymeric matrix is greater than the particle, the refractive index will decrease as one moves from the outer surface of the particle to the inorganic core. If the refractive index of the polymeric matrix is lower than the particle, the refractive index will increase as one moves from the outer surface of the particle to the inorganic core. Assuming a brush-like particle, wherein linear polymer chains radiate outwardly from the core, the amount of polymer chains per a given area will increase as one moves closer to the core. Because there is a higher ratio of polymeric matrix to polymer chains near the edge of the particle, while near the inorganic core there is a higher ratio of polymer chains to polymeric matrix, this causes a continuously varying refractive index from the edge of the particle to the inorganic core. In one embodiment, the change in refractive index is linear, while in other embodiments the change in refractive index is not linear.

It has been found that compositions of the present description can provide various optical properties that may be useful in certain applications. For example, in some embodiments, the composition containing the particles is used to form a film or an adhesive layer or one or more layers of a film including a plurality of layers. Such film or layers may be used to provide a light diffusing layer that may be used in a display application or solar application.

In some embodiments, the compositions of the present disclosure are applied onto a substrate via for example, coating or extruding, to form an optical film or one or more layers in an optical film. In some embodiments, the compositions of the present description may be injection molded into a part.

FIG. 2 is a cross-sectional view of layer 28, which may be a scattering control layer. Layer 28 includes a plurality of grafted inorganic core particles 20 which may correspond to any of the particles described herein. A collimated beam of light 21 is schematically illustrated in FIG. 2. When collimated beam of light 21 passes through layer 28 an output distribution 23 of light is produced.

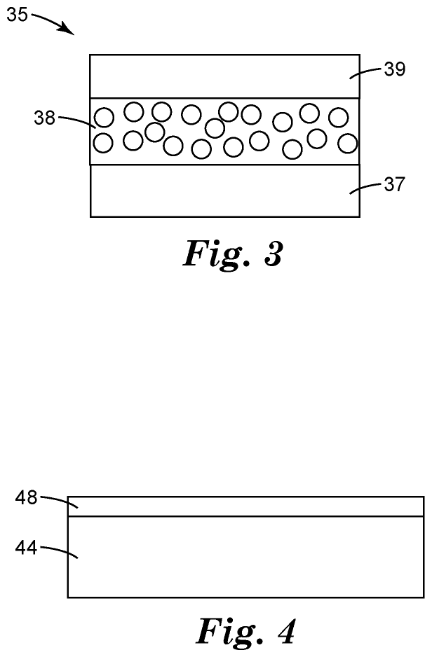

In some embodiments, a multilayer film is provided where at least one layer of the multilayer film is a composition that includes compositions according to the present description. An example is illustrated in FIG. 3 which shows a multilayer film 35 having three layers including layer 38, which may correspond to layer 28, for example. Multilayer film further includes layer 39, which may be a hard coat layer, for example, and layer 37, which may be an adhesive layer for example. The hard coat layer may be formed from a resin that, when cured, is hard enough to provide adequate pencil hardness or abrasion resistance in applications where the material can be an outer layer. For example, the cured hard coat resin may provide a pencil hardness greater than HB or greater than H. Suitable hard coat resins include acrylic resins that may include inorganic nanoparticles. Suitable adhesive layers, which may be optically clear adhesive layers, include pressure sensitive adhesives (PSAs) and hot-melt adhesives. Useful adhesives that may be used in layer 37 and/or that may be used as the matrix in layer 38 include elastomeric polyurethane or silicone adhesives and the viscoelastic optically clear adhesives CEF22, 817x, and 818x, all available from 3M Company, St. Paul, Minn. Other useful adhesives include PSAs based on styrene block copolymers, (meth)acrylic block copolymers, polyvinyl ethers, polyolefins, and poly(meth)acrylates. Multilayer film 35 may be used as a diffusing control film that can be adhered to an outer surface of a display.

FIG. 4 schematically illustrates film or layer 48 disposed on a display 44. Film or layer 48 may correspond to layer 28 or multilayer film 38, for example. Film or layer 48 may be a wide angle scattering layer, for example.

In some aspect of the present description, one or more ordered layers of the particles described herein is provided. The total number of layers may be, for example in a range of 1 to 3. Using only a few layers (e.g., one, two or three layers) allows the optical effects of individual particles to be retained.

Unexpectedly, it has been discovered the compositions of the present disclosure have a wider angle of scattering as compared to the same composition wherein the grafted particles are replaced by ungrafted inorganic particles having a similar refractive index (within 0.05) and a similar diameter D (within 200 nm) (i.e., having a constant index of refraction).

In one embodiment, the increased scatter can be observed by measuring the optical properties of the compositions. In one embodiment, the compositions of the present disclosure have reduced clarity, while transmission and/or haze are not substantially impacted. Transmission is the amount of visible light that passes through the sample and reaches the detector. Light that is absorbed, scattered or reflected is not transmitted. In one embodiment, the compositions of the present disclosure transmit at least 80, 85, 90, or even 95% of the incident light. Of the light transmitted through the sample, haze refers to the percentage of light that deviates more than 2.5 degrees from the incident beam. Haze is a measure of the wide angle scattering and results in a reduction in contrast. In one embodiment, the constructions of the present disclosure have a haze of less than 15, 10, 5, or even 2%. Clarity refers to transmitted light that deviates less than 2.5 degrees from the incident beam. Clarity is a measure of narrow angle scattering and relates to the resolution of detail of objects viewed through a sample. Clarity is a distance-dependent attribute, for example, decreasing as the distance between sample and object increases. In one embodiment, the sample is placed next to an illumination source and a sensor (comprising a center sensor and a ring sensor) is placed at a given distance from the illumination source. Clarity can be defined as

$$100 \% \cdot \frac{{I}_{C} - {I}_{R}}{{I}_{C} + {I}_{R}}$$

where I_{C} is the intensity at the center sensor and I_{R} is light intensity at the ring sensor. No clarity (or 0%) would be equal intensity at the center and ring sensor, and 100% clarity would be zero intensity at the ring sensor (i.e. no light diverted less than 2.5 degrees from the incident light beam). In one embodiment, the constructions of the present disclosure have a clarity of greater than 70, 75, 80, 85, or even 90%, but less than 95, 98, or even 99% using the method disclosed in the example section. In one embodiment, the compositions of the present disclosure have a reduction in clarity of at least 2, 5, or even 10% versus the clarity of the same composition wherein the grafted particles are replaced by inorganic particles having a constant index of refraction (i.e., a constant index particle, which is an ungrafted particle having the same refractive index and approximately the same diameter D (e.g., within 20, 10 or even 5% or even the same diameter) as the grafted inorganic particles of the present disclosure).

In one embodiment, the increased scatter can be observed by modeling as described in the Example Section below by comparing a composition comprising the grafted particle disclosed herein versus a composition comprising a particle having a constant index of refraction. The angle of scatter that occurs when a collimated beam of light passes through the particle can be simulated to show the light intensity at various angles from the angle of incidence. Plotting the light intensity versus angle provides a half-Guassian type scattering distribution peak, where as you move away from 0 degrees (angle of incidence) the light intensity rapidly decreases to approach 0. The full width at half maximum for the scattering distribution peak is broader for the particles of the present disclosure as compared to a constant index particle. In one embodiment, the full width at half maximum for the scattering distribution peak for the particle of the present disclosure is at least 20, or even 30% wider at the full width at half maximum for the scattering distribution peak than for a constant index particle.

In one embodiment, when a collimated beam of light passes through a single particle of the present disclosure in a polymeric matrix, the scattering cross section efficiency of the particle will be reduced in comparison to a constant index particle. The scattering cross section efficiency is defined as the scattering cross section of the particle divided by the particle cross-sectional area projected onto a plane perpendicular to the incident beam. (See C. Bohren, D. Huffman, Absorption and Scattering of Light by Small Particles, Wiley, New York, 1983). This reduction may be at least 40, 50, 60, or 70% and no greater than 100% compared with a constant index particle of the same size.

The increased angle of scatter may be useful in applications such as organic light emitting diode (OLED) displays or solar panels.

In one embodiment, the substrate comprises polyethylene terephthalate or an organic light emitting diode (OLED) stack, wherein the composition of the present disclosure is adhered to a surface comprising at least one OLED.

### EXAMPLES

Unless otherwise noted, all parts, percentages, ratios, etc. in the examples and the rest of the specification are by weight, and all reagents used in the examples were obtained, or are available, from general chemical suppliers such as, for example, Sigma-Aldrich Company, Saint Louis, Mo., or may be synthesized by conventional methods.

Material abbreviations used in the Examples are listed in Table 1 below.

TABLE 1
Raw materials and sources

| Material | Description |
|---|---|
| Particle 1 | 190 nanometer (nm) diameter silica particles dispersed in |
| | water, obtained under the trade designation SNOWTEX MP- |
| | 2040 from Nissan Chemical Company (Tokyo, Japan) |
| Bromide initiator silane | 3-trimethoxysilyl)propyl 2-bromo-2-methylpropionate of the |
| | structure shown below (CAS No. 314021-97-1) |
| | 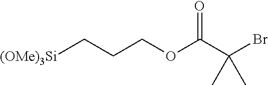 |
| | from Gelest, Inc. (Morrisville, PA) |
| Copper wire | Copper wire (18 gauge) was cleaned by wrapping around a stir |
| | bar and stirring while immersed in glacial acetic acid held at 40° C. |
| | for 1 hour. The wire was immediately dried under vacuum |
| | overnight and then stored in an inert atmosphere glovebox. |
| MA | Methyl acrylate (MA) (from Fisher Scientific (Hampton, NH) |
| | was treated to remove inhibitor before use by passing through a |
| | 5 centimeter (cm) column of basic alumina. The MA was then |
| | stored over 3 Angstrom molecular sieves in a Schleck flask for |
| | 1 hour, degassed with bubbling N₂ for 10 minutes, and then |
| | transferred into a glove box and used immediately. |
| DMSO | Dimethyl sulfoxide (anhydrous grade) (from VWR |
| | International (Radnor, PA)) was stored in an inert atmosphere |
| | glovebox. |
| ME₆-TREN | tris(2-dimethylaminoethyl)amine (from Fisher Scientific |
| | (Hampton, NH)) was stored and handled in an inert atmosphere |
| | glovebox. |
| Polysulfone | Polysulfone had an average Mₙ of 26,000 Daltons from Sigma |
| | Aldrich (St Louis, MO) |
| Particle 2 | A dry powder of amorphous silica with an average diameter of |
| | 1 micron obtained under the trade designation |
| | ANGSTROMSPHERE from Fiber Optic Center (New Bedford, |
| | MA) |
| ethylxanthic acid potassium | 98% purity from Alfa Aesar (Tewksbury, MA) |
| salt | |
| (p-chloromethyl)- | Gelest, Inc. (Morrisville, PA) |
| phenyltrimethoxysilane | |
| Particle 3 | Surface-modified zirconia (ZrO₂) nanoparticles with an average |
| | particle size less than 20 nm dispersed at 64% by weight in |
| | diethylene glycol monomethyl ether. Preparation of this sol is |
| | described in U.S. Pat. Publ. No. 2006/0204745 (Jones, et al.) |
| 2-phenyl-phenyl acrylate | Available from ToaGosei (Tokyo, Japan) under trade |
| | designation TO-2344. This material was purified by passing |
| | through a 4 cm column of basic alumina immediately before |
| | use. |
| Vazo-67 | 2,2′-azodi(2-methylbutyronitrile), available from Dupont under |
| | trade designation Vazo-67 from E. I. du Pont de Nemours and |
| | Company (Wilmington, DE) |

Nuclear Magnetic Resonance (NMR) Spectroscopy Test Method

¹H NMR spectra were measured using a Bruker Ultrashield Plus 500 megahertz instrument (Billerica, Mass.). Consumption of monomer during polymerization was measured by diluting reaction aliquots with CDCl₃ and recording ¹H spectra. Monomer consumption was inferred by measuring the change in integration of monomer peaks relative to DMSO, which served as an internal standard.

Dynamic Light Scattering (DLS) Test Method

Gradient particle size was measured in dilute tetrahydrofuran (THF) solution by dynamic light scattering using a Malvern ZETASIZER NANO analyzer (Malvern Instruments, Malvern, UK). Measurements were taken in a quartz cuvette. For modeling the particle size, the particles were assumed to have an average refractive index of 1.45.

Optical Property Measurement (% Transmission, % Haze, and % Clarity) Test Method

Total transmittance, haze, and clarity measurements were made using a BYK Haze-Gard Plus, Model No. 4725 (BYK-Gardner USA, Columbia, Md.), an integrating sphere instrument having 0°/diffuse geometry and CIE standard illuminant C. Samples were placed directly at the haze port for measurement of transmittance and haze and at the clarity port for measurement of clarity. Reported values are an average of three measurements. Error values are reported as one standard deviation.

Preparative Sample 1: Surface Functionalization of Particle with Bromine Initiator

A 500 mL round-bottom flask was charged with 50.00 grams (g) of a dispersion of Particle 1 (41.90% solids, 20.95 g Particle 1) and 35 g of 1-methoxy-2-propanol. Separately, 483 milligrams (mg) (1.47 mmoles) of bromide initiator silane was dissolved in 10 g of 1-methoxy-2-propanol. This solution was added to the round-bottom flask dropwise with stirring. An additional 5 g of 1-methoxy-2-propanol was used to wash the vial that contained the silane solution, and these washings were also added to the round-bottom flask. A condenser was attached to the round-bottom flask, and the dispersion was heated in an oil bath held at 80° C. overnight. The solvent was then removed by distillation under reduced pressure. 200 milliliters (mL) of water was added to the resulting powder and the resulting dispersion was stirred for 1 hour. The dispersion was then centrifuged at 3400 revolutions per minute (rpm) for 20 minutes, and the supernatant was discarded. Another 200 mL of water was added to the solid powder, and the resulting dispersion was sonicated for 1 hour. The dispersion was again centrifuged at 3400 rpm for 90 minutes, and the supernatant discarded. The resulting white powder was dried under vacuum and stored in an inert atmosphere glovebox.

Preparative Sample 2: Polymerization of Methyl Acrylate from the Surface of Bromine-Functional Particle

In an inert atmosphere glovebox, a vial was charged with the particles of Preparative Sample 1 (1.00 g) and DMSO (9 g). The vial was sealed, removed from the glovebox, and sonicated until a nearly clear dispersion was obtained. This dispersion contains a calculated 0.0069 mmoles of bromide initiator per gram. The vial was returned to the glovebox. A second vial was charged with 1.40 g of this particle dispersion (4.84 micromole (mop of bromide initiator, 1 equivalent), 13.3 g of additional DMSO, 2.50 g of methyl acrylate (MA) (6000 equivalents), and 223 mg of ME₆-TREN diluted to 0.1 weight percent (wt. %) in DMSO (0.968 μmoles, 0.2 equivalents). A 100 mg aliquot was removed for NMR analysis. A 5 cm section of copper wire was wrapped around a TEFLON stir bar and added to the vial to start the reaction, which was run on hot plate that was equilibrated to 35° C. Reaction progress was monitored by proton NMR analysis of aliquots in CDCl₃. After 360 minutes, the reaction was stopped by removing the copper wire and exposing the reaction to air. NMR analysis suggests that 24% by mole of monomer converted to polymer. Any gel that had formed around the wire was discarded, and the remaining solution was diluted with 80 g of acetone. This dispersion was centrifuged at 6000 rpm for 20 minutes and the supernatant was discarded. The solid was re-dispersed in 100 g of acetone, and then centrifuged at 6000 rpm for 20 minutes. The supernatant was discarded and the resulting clear solid was dried under vacuum yielding 460 mg (18% yield).

TABLE 2
Reagent amounts used in Preparative Example 2

| Reagent | Moles | Mass | Concentration | Equivalents |
|---|---|---|---|---|
| Preparative Example | 4.84 μmol | 0.701 g | 0.069 mmol/g (particles), | 1 |
| 1 | | | 10% in DMSO | |
| Additional DMSO | — | 16.76 g | | |
| ME₆-TREN | 0.484 μmol | 112 mg | 0.1% in DMSO | 0.1 |
| MA | 29.0 mmol | 2.50 g | | 6000 |

Analysis of Grafted Particles by Dynamic Light Scattering

The grafted particles from Preparative Sample 2 were dissolved at 2 wt. % in tetrahydrofuran (THF) by stirring overnight. The dispersion was then filtered through a 1 micron glass fiber syringe tip filter. This dispersion was diluted by adding 6 drops to 1 mL of THF, and analyzed by DLS as mentioned above assuming a spherical particle. The measured particle diameter showed a median particle diameter of 1.01 micron with a polydispersity of 1.57.

Preparative Sample 3: Polymerization of Methyl Acrylate from the Surface of Bromine-Functional Particles

A polymerization was conducted according to the procedure as described in Preparative Sample 2 using the reagent amounts shown in Table 2. The reaction was stopped after 23 hours. NMR analysis suggests that 29% of monomer converted to polymer. After purification by twice repeated dilution with acetone and centrifugation as described in Preparative Sample 2, 546 mg of solid was obtained (21% yield).

Preparative Sample 4: Synthesis of a Photoiniferter Silane

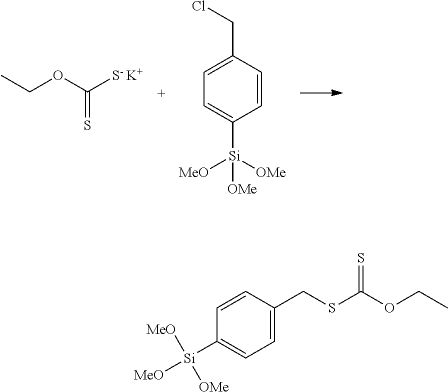

A 4 ounce brown glass jar was charged with 1.50 g of ethylxanthic acid potassium salt (9.36 mmoles), 2.10 g of (p-chloromethyl)phenyltrimethoxysilane (8.51 mmoles), and 20 mL of acetone. The jar was sealed and the suspension was stirring overnight. Solids were removed by filtering the suspension through a PTFE syringe tip filter with a 5 micron pore size (Whatman, Maidstone, UK). The solvent was evaporated with a stream of nitrogen and the resulting clear oil was dried overnight under vacuum.

Preparative Sample 5: Surface Functionalization of Particles

An 8 ounce brown glass jar was charged with 39.36 g of a dispersion of Particle 1 (41.10% solids, 16.18 g Particle 1), 210 mg of acetic acid (3.50 mmoles), and 30 g of 1-methoxy-2-propanol. Separately, 377 mg (1.13 mmoles) of the photoiniferter silane of a dispersion of Preparative Sample 4 was dissolved in 5 g of 1-methoxy-2-propanol. This solution was added to the jar dropwise with stirring. An additional 5 g of 1-methoxy-2-propanol was used to wash the vial that contained the silane solution, and these washings were also added to the jar. The jar was sealed and placed in an oven held at 70° C. overnight. The resulting dispersion was cooled to room temperature, diluted with 40 mL of isopropanol, and transferred to centrifuge tubes. The dispersion was then centrifuged at 6000 rpm for 20 minutes, and the supernatant was discarded. The solid silica was re-dispersed in 80 mL of ethyl acetate using a combination of sonication and stirring. The dispersion was centrifuged at 6000 rpm for 120 minutes, and the supernatant discarded. The resulting white powder was dried under vacuum and stored in an inert atmosphere glovebox.

Preparative Sample 6: Polymerization of Methyl Acrylate from the Surface of Photoiniferter-Functional Particle:

In an inert atmosphere glovebox, a vial was charged with the particles of Preparative Sample 5 (1.00 g) and DMSO (9 g). The dispersion was stirred for several hours until a nearly clear dispersion was obtained. This dispersion contains a calculated 0.0069 mmoles of photoiniferter per gram. A second vial was charged with 1.12 g of this particle dispersion (7.74 μmol of photoiniferter, 1 equivalent), 11.0 g of additional DMSO, and 4.00 g of MA (46.5 mmoles, 6000 equivalents). This vial was sealed and removed from the glovebox. The vial was placed in a box lined with reflective aluminum foil and covered with a lamp outfitted with 2 25 watt blacklight 350 nm bulbs (Sylvania, Wilmington, Mass.). This box was placed above a stir plate and the solution was stirred while the vial was illuminated for 1 hour. The resulting viscous solution was diluted with 50 mL of ethyl acetate and centrifuged at 6000 rpm for 20 hours. The supernatant was discarded and the solid was re-dispersed in 50 mL of acetone. The dispersion was centrifuged at 6000 rpm for 4 hours. The supernatant was discarded and the remaining material was dried under vacuum yielding 924 mg of soft, opalescent solid. The refractive index of Particle 1 was about 1.46, the refractive index of the polymethacrylate was about 1.48.

Preparative Sample 7: Polymerization of 2-Phenyl-Phenyl Acrylate

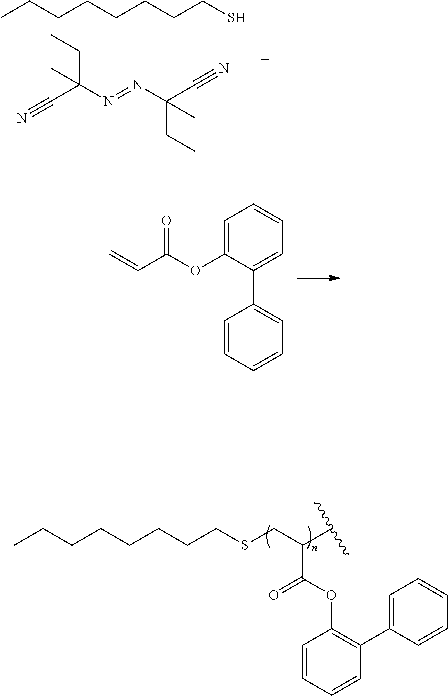

A 100 mL round-bottom flask was charged with 10.0 g (4.46 mmol) of 2-phenyl-phenyl acrylate, 25 g of ethyl acetate, 109 mg of 1-octanethiol (0.379 mmol), and 7.3 mg of Vazo-67 (0.038 mmol). The flask was capped with a rubber septum and nitrogen was bubbled through the solution via a needle for 10 minutes. The flask was then placed in an oil bath held at 70° C. and the solution was stirred under a blanket of nitrogen for 6 hours. The solution was then poured slowly into 300 mL of isopropanol while stirring. The resulting precipitate was isolated by filtration, washed with excess isopropanol, and dried under vacuum. This yielded 8.7 g of polymer as a white powder.

### Comparative Example A (CE-A)

A polysulfone solution was made by dissolving polysulfone in THF at a concentration of 10% by weight. The refractive index of the polysulfone was about 1.63.

### Example 1 (EX-1)

The particles of Preparative Sample 6 were dispersed in THF at a concentration of 10% by weight by stirring overnight. A 5% coating solution was made by dispersing 0.3125 g of the dissolved particles into 2.70 g of a polysulfone solution (10% by weight in THF).

### Comparative Example B (CE-B)

To compare EX-1 against a composite comprising a similar particle diameter, a coating solution was made as follows. Particle 2 was dispersed in THF at a concentration of 10% by weight using sonication. A 5% coating solution was made by dispersing 0.500 g of the dispersed particles into 9.50 g of a polysulfone solution (10% by weight in THF).

EX-1, CE-A and CE-B were coated onto 2 mil (0.05 mm) thick polyester film using a 0.8 mil (20 micron) wire wound rod available from BYK, Inc. The expected wet coating thickness was 20 microns. After solvent evaporation, the optical properties were measured and are shown in Table 3 below.

TABLE 3

| Coating | % Haze | % Transmission | % Clarity |
|---|---|---|---|
| CE-A | 1.48 ± 0.50% | 89.1 ± 0.10% | 99.7 ± 0.12% |
| EX-1 | 11.7 ± 0.52% | 89.6 ± 0.12% | 88.5 ± 1.31% |
| CE-B | 9.25 ± 0.16% | 89.1 ± 0.06% | 98.8 ± 0.15% |

As shown in table 3 above, EX-1 had a similar transmission as CE-B, but almost 10% less clarity than CE-B, which comprised particles of about the same size.

### Comparative Example C (CE-C)

The polymer of preparative sample 7 was dissolved at 12.5% by weight in a mixture of 5:3 methyl ethyl ketone (MEK):toluene. Particle 3 was diluted with MEK to a concentration of 12.5% solids. The two solutions/dispersions were then mixed at a weight ratio of 4:1 polymer:particle to create a coating solution that once dried has an estimated refractive index of 1.65.

### Example 2 (EX-2)

The particles of Preparative Sample 6 were dispersed in THF at a concentration of 10% by weight by stirring overnight. A 5% coating solution was made by dispersing 0.200 g of the 10% particle dispersion in THF with 3.04 g of the coating solution of CE-C. This mixture was stirred for 1 hour before coating.

### Comparative Example D (CE-D)

To compare EX-2 against a composite comprising a similar particle diameter, a coating solution was made as follows. Particle 2 was dispersed in MEK at a concentration of 10% by weight using sonication. A 5% coating solution was made by mixing 0.200 g of the 10% particle dispersion in MEK into 3.04 g of the coating solution of CE-C.

EX-2, CE-C, and CE-D were coated onto 2 mil (0.05 mm) thick polyester film using a 0.65 mil (16 micron) wire wound rod available from BYK, Inc. The expected wet coating thickness was 16 microns. After solvent evaporation, the optical properties were measured and are shown in Table 4 below.

TABLE 4

| Coating | % Haze | % Transmission | % Clarity |
|---|---|---|---|
| CE-C | 12.4 ± 0.83% | 89.4 ± 0.26% | 91.6 ± 0.80% |
| EX-2 | 26.6 ± 0.30% | 89.8 ± 0.0% | 68.4 ± 3.19% |
| CE-D | 23.4 ± 0.98% | 89.4 ± 0.26% | 91.6 ± 0.80% |

As shown in Table 4 above, EX-2 had a similar transmission as CE-D, but 23% less clarity than CE-D, which comprised particles of about the same size.

### Example 3: Simulation of the Optical Properties of a Composition of the Present Disclosure

The optical properties of particles dispersed in a matrix were calculated using Mie scattering in a multilayered sphere model as described in Pena, et al., Computer Physics Communications, 180, 2009, 2348-2354, herein incorporated by reference. As described above, the grafted inorganic core particles of the present disclosure are thought to interact with the polymeric matrix, resulting in a varying refractive index which changes from the polymeric matrix to the inorganic core. Thus, the particle of the present disclosure was simulated as a series of concentric differential layers with a linearly varying refractive index. Specifically, the particles were modeled as having a core (first region) with a refractive index of 1.46 (similar to the refractive index of the core used in Example 1) and an outer region (second region) with refractive index that varies in a linear fashion from 1.46 adjacent to the core to 1.70 (similar refractive index of the polymeric matrix used in Example 1) at the surface of the particle using hundreds of layers. The core diameter was 0.2 micrometers and the particles had an outer diameter of 2 micrometers (1 micrometer radius). The particles were assumed to be dispersed in a matrix having a refractive index of 1.70. The particles were assumed to have a low particle density so that the scattering profile determined by a single particle would be representative of the light diffusing layer. The far field electric field squared (|E|²) was determined by the simulation software and this is proportional to the intensity of the transmitted light. The scattering cross section efficiency was also reported by the simulation software, which is the characteristic property of particle scattering. Since the incident light was assumed to be unpolarized, light intensity at various scattered angles from a normal angle of incidence was calculated by averaging that from two orthogonal incident polarizations. Using the simulation software, light intensity was reported for a variety of angles from the incident angle. The scatter angle at the FWHM (full width at half maximum) was about 6.5 degrees, and the scattering cross section efficiency was 1.09.

### Comparative Example E: Simulation of the Optical Properties of a Composite Comprising Ungrafted Particles

The simulation as described in Example 3 was repeated except that the particles had a 2 micrometer-diameter (1 micrometer radius) and a constant refractive index of 1.46 in a matrix of refractive index 1.70. The scatter angle at the FWHM was about 5 degrees (i.e., smaller angle of scatter than Example 3). The scattering cross section efficiency was 2.14.

Foreseeable modifications and alterations of this invention will be apparent to those skilled in the art without departing from the scope and spirit of this invention. This invention should not be restricted to the embodiments that are set forth in this application for illustrative purposes. To the extent that there is any conflict or discrepancy between this specification as written and the disclosure in any document mentioned or incorporated by reference herein, this specification as written will prevail.

1. A composition comprising:
a polymeric matrix having a first refractive index, and
a first plurality of particles dispersed therein, wherein each particle within the first plurality of particles comprises an inorganic core with polymer chains grafted thereon, wherein the particle has a second refractive index that is different from the first refractive index.

2. The composition of claim 1, wherein the inorganic core and polymer chains have substantially the same refractive index.

3. The composition of claim 1, wherein each particle within the first plurality of particles displays a continuously varying refractive index change from the first refractive index to the second refractive index.

4. The composition of claim 1, wherein the difference between the first refractive index and the second refractive index is greater than 0.1.

5. The composition of claim 1, wherein the inorganic core comprises at least one of silica, alumina, and combinations thereof.

6. The composition of claim 1, wherein the inorganic core has a refractive index less than 1.7.

7. The composition of claim 1, wherein the inorganic core has an average diameter of at least 50 nm to at most 500 nm.

8. The composition of claim 1, wherein the polymer chains are not crosslinked.

9. The composition of claim 1, wherein the polymer chains have a number average molecular weight of at least 50,000.

10. The composition of claim 1, wherein the polymer chains are derived from a monomer comprising at least one of acrylate, methacrylate, acrylamide, methacrylamide, polyamide, polyesters, polyether, olefin, styrene, or combinations thereof.

11. The composition of claim 1, wherein the particles have an average diameter of at least 100 nm and at most 5 microns.

12. The composition of claim 1, wherein the polymeric matrix comprises at least one of polyacrylates, polymethacrylates, polyolefins, polyepoxides, polyethers, polyimides, polyamides, thiol-ene polymers, conjugated aromatic polymers, and combinations thereof.

13. The composition of claim 1, wherein the polymeric matrix comprises at least one of epoxide monomers, acrylate monomers, methacrylate monomers, thiol-ene monomer, and combinations thereof.

14. The composition of claim 13, further comprising a crosslinking agent.

15. The composition of claim 1, wherein the composition is translucent or transparent.

16. The composition of claim 1, wherein the composition comprises at least 2% and at most 40% by weight of the plurality of first particles versus polymeric matrix.

17. The composition of claim 1, wherein the polymeric matrix further comprises a second plurality of particles.

18. The composition of claim 17, wherein the second plurality of particles has a diameter less than 20 nm.

19. The composition of claim 17, wherein the second plurality of particles comprises at least one of zirconia, titania, zinc oxide, and combinations thereof.

20. A coated article comprising a substrate and the composition of claim 1.

21. The coated article of claim 20, wherein the substrate comprises at least one organic light emitting diode.

22. The coated article of claim 21, wherein the substrate comprises polyethylene terephthalate.

23. A light diffusing layer comprising the composition of claim 1.

24. The light diffusing layer of claim 23, wherein when a collimated beam of light passes through a single particle in the light diffusing layer, the scattering cross section efficiency will be reduced in comparison to a constant index particle.

25. The light diffusing layer of claim 24, wherein the scattering cross section efficiency is reduced by at least 40% compared with the constant index particle.

26. The light diffusing layer of claim 23, wherein when a collimated beam of light passes through a single particle in the light diffusing layer, the full width at half maximum of the scattering distribution peak is broadened in comparison to a constant index particle.

27. The light diffusing layer of claim 26, wherein the full width at half maximum of the scattering distribution peak is at least 20% wider than that of the constant index particle.

28. The light diffusing layer of claim 23, wherein the light diffusing layer has a reduced clarity in comparison to a layer identical to the light diffusing layer which is made with a constant index particle.
